(19) United States
(12) Patent Application Publication
(10) Pub. No.: US 2024/0289676 A1
(43) Pub. Date: Aug. 29, 2024

(54) NON-CLIFFORD QUANTUM GATES

(71) Applicant: University of Technology, Sydney, Ultimo, New South Wales (AU)

(72) Inventor: Simon John Devitt, Ultimo, New South Wales (AU)

(73) Assignee: University of Technology, Sydney, Ultimo, New South Wales (AU)

(21) Appl. No.: 18/566,621

(22) PCT Filed: Jun. 1, 2022
(86) PCT No.: PCT/AU2022/050536

§ 371 Date: Dec. 1, 2023

(30) Foreign Application Priority Data
Jun. 4, 2021 (AU) 2021901663

(51) Int. Cl. G06N 10/70; G06N 10/40

(52) U.S. Cl. CPC G06N 10/70; G06N 10/40

(57) ABSTRACT

This disclosure relates to processing encoded quantum information in a quantum computer using a stabilizer quantum error correction code. Multiple physical data qubits operable in a stabilizer quantum error correction code. A first quantum circuit operates on the multiple physical data qubits and comprises a physical non-Clifford gate to initialise physical states of the multiple physical data qubits in a logical block of the stabilizer quantum error correction code, to define an encoded quantum state encoded by the physical data qubits in the logical block. A second quantum circuit operates on the encoded quantum state and on encoded quantum information and comprises only one or more logical Clifford gates to realise, by taking the encoded quantum state as an input, a logical non-Clifford gate on the encoded quantum information. As a result, the overhead is significantly reduced compared to alternative approaches, such as magic-state distillation.

### CROSS-REFERENCE TO RELATED APPLICATIONS

The present application claims priority from Australian Provisional Patent Application No 2021901663 filed on 4 Jun. 2021, the contents of which are incorporated herein by reference in their entirety.

### TECHNICAL FIELD

This disclosure relates to processing error corrected quantum information using non-Clifford quantum gates.

### BACKGROUND

Quantum computers promise a significant increase is computational power compared to classical computers. Classical computers operate on binary (one/zero) states, referred to as bits. Operations on binary input data can be reduced to a sequence of Boolean logic gates, such as NAND gates. When combined, NAND gates can be used to build all possible binary logic functions.

Similarly, in quantum computers, there are basic operations that are also referred to as “quantum gates” (or synonymously “quantum logic gates”). In contrast to classical computers, quantum gates operate on quantum states. The quantum state can be visualised in a Bloch sphere as shown in FIG. 1, that is, the quantum state can be anywhere on the Block sphere 100. The Bloch sphere 100 comprises two ‘pure’ states 10> at 101 and 1> at 102. These two states are comparable to binary states in classical computers. However, there are also four superposition states 1+i> at 103, -i> at 104, |+> at 105, and |−-> at 106.

The four superposition states 103-106 can be reached from the ground state 101 by the application of appropriate quantum gates. More particularly, the six states 101-106 can be reached by the application of relatively ‘simple’ gates, which are referred to as Clifford gates. There is a number of potential Clifford gates but not all are necessary to reach the states 101-106. One example set of Clifford gates is composed of the CNOT, H and S gates.

As can be seen from FIG. 1, however, there is a large area on the Bloch sphere that cannot be reached by the ‘simple’ Clifford gates. Therefore, any set of only Clifford gates is not universal as stated by the Gottesman-Knill theorem. In fact, any quantum computation involving only Clifford gates can be simulated on a classical computer relatively easily. The real computational advantage of quantum computing arises only when the remaining area on the Bloch sphere can be reached.

For that purpose it is necessary to introduce at least one relatively ‘complicated’ non-Clifford gate into the gate set. In many cases, this non-Clifford gate is a T gate, which is a phase shift gate of:

$$P ( φ ) = [ \begin{matrix}1 & 0 \\ 0 & {e}^{i φ}\end{matrix} ] with φ = \frac{π}{4} .$$

T gates can be implemented with the use of ancilla qubits only under theoretically ideal conditions. It is one of the main problem of quantum computing that the level of noise is high, which makes quantum states extremely unstable. In order to address this problem, error correction codes have been developed, which leverage the knowledge from classical code theory for the correction of quantum errors. One such example code is the surface code, a stabilizer based quantum error correction code consisting of a block of physical qubits encoding logical data and ancillary qubits used to extract error information from this logical data block.

Such stabilizer error correction codes operate on blocks and perform encoded operations between the blocks. Further, these codes implement ‘simple’ Clifford gates with relatively low overhead. However, as described above, meaningful quantum computation cannot be performed with only Clifford gates. In order to implement a non-Clifford gate in a surface code, an immense overhead is currently required, which can be an overhead of 10,000 physical qubits required to implement a single qubit non-Clifford gate on a single block of encoded data. This overhead is required to perform ancillary protocols for realising non-Clifford gates, such as magic-state distillation, which requires a large number of operations to ‘distil’ the desired quantum state to a desired low error rate. Given that current manufacturing technologies can only manufacture a relatively small number of qubits, it is difficult to manufacture physical qubit arrays of sufficient size that would enable the implementation of gates with such a large overhead, for practical applications.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

This disclosure provides a method for processing quantum information in a quantum computer with a significantly reduced overhead. The disclosed method initialises physical data qubits such that they represent an encoded state of a logical block of the stabilizer code. However, instead of initialising the physical qubits in a state that is reachable by application of a Clifford gate, the physical qubits are initialised by application of a non-Clifford gate on the physical qubit level. It is noted that the non-Clifford gate on the physical qubit level has a relatively low overhead compared to non-Clifford gates on the logical (block) level. It has been found, that as a result of initialising the physical qubits by the application of non-Clifford gates, the resulting logical state of the block can be used to realise a non-Clifford gate on the block level. As a result, the overhead of qubits is significantly reduced compared to alternative approaches, such as magic-state distillation.

The analytic formalism provided herein to calculate the logically encoded state is general and applies to all stabiliser codes without major alterations. Further, the transversal injection formalism disclosed herein and analytical calculations apply to all quantum error correction code strengths (distances). Further, the disclosed protocols and methodologies work on any physical embodiments of quit systems utilising quantum error correction. Further, the disclosed transversal injection is also functional on other quantum computing systems based on d-level quantum systems (qudits) and continuous variable quantum systems.

A method for processing encoded quantum information in a quantum computer using a stabilizer quantum error correction code comprises:
initialising physical states of physical data qubits in a logical block of the stabilizer quantum error correction code by applying a physical non-Clifford gate to each of the physical data qubits, to define an encoded quantum state encoded by the physical data qubits in the logical block; and
evaluating the stabilizer quantum error correction code to realise a desired quantum logic function and suppress quantum errors,
wherein evaluating the stabilizer quantum error correction code comprises consuming the encoded quantum state, resulted from applying the physical non-Clifford gate to each of the physical data qubits, to realise a logical non-Clifford gate on the encoded quantum information.

In some embodiments, the physical states for initialising the physical data qubits in the logical block are identical.

In some embodiments, the method further comprises determining the physical states based on a desired logical non-Clifford gate on the encoded quantum information.

In some embodiments, determining the physical states comprises solving one or more equations for two factors that define a superposition of two respective ground states of the physical data qubits.

In some embodiments, the one or more equations are based on a code distance of the stabilizer quantum error correction code.

In some embodiments, the method further comprises determining the encoded quantum state based on the physical non-Clifford gate applied to each of the physical data qubits.

In some embodiments, determining the encoded quantum state comprises analytically calculating the encoded quantum state as a function of the physical non-Clifford gate.

In some embodiments, the method further comprises extracting syndrome information by measuring multiple physical ancilla qubits to suppress the quantum errors.

In some embodiments, the logical non-Clifford gate on the encoded quantum information is a T gate.

In some embodiments, the logical non-Clifford gate together with one or more logical Clifford gates, form a universal gate set for universal error-corrected computation.

In some embodiments, the number of data qubits is identical to the number of data qubits required to realise logical Clifford gates.

In some embodiments, the stabilizer quantum error correction code comprises a surface code.

In some embodiments, realising the logical non-Clifford gate comprises using the encoded quantum information and the encoded quantum state as respective inputs to a Clifford gate.

In some embodiments, the Clifford gate is a CNOT gate.

In some embodiments, one or both of the physical non-Clifford gate and the logical non-Clifford gate is a rotated gate.

A quantum processor comprises:
multiple physical data qubits operable in a stabilizer quantum error correction code; and
a control system configured to:
   initialise physical states of the multiple physical data qubits in a logical block of the stabilizer quantum error correction code by applying a physical non-Clifford gate to each of the physical data qubits, to define an encoded quantum state encoded by the physical data qubits in the logical block; and
   evaluate the stabilizer quantum error correction code to realise a desired quantum logic function and suppress quantum errors,
   wherein evaluating the stabilizer quantum error correction code comprises consuming the encoded quantum state, resulted from applying the physical non-Clifford gate to each of the physical data qubits, to realise a logical non-Clifford gate on the encoded quantum information.

A quantum processor comprising: multiple physical data qubits operable in a stabilizer quantum error correction code;
a first quantum circuit configured to operate on the multiple physical data qubits and comprising a physical non-Clifford gate to initialise physical states of the multiple physical data qubits in a logical block of the stabilizer quantum error correction code, to define an encoded quantum state encoded by the physical data qubits in the logical block; and
a second quantum circuit configured to operate on the encoded quantum state and on encoded quantum information and comprising only one or more logical Clifford gates to realise, by taking the encoded quantum state as an input, a logical non-Clifford gate on the encoded quantum information.

It is noted that optional features provided in relation to the method are equally optional features of the quantum processor.

### BRIEF DESCRIPTION OF DRAWINGS

FIG. 1 illustrates a Bloch sphere to visually represent a physical or logical quantum state.

An example will now be described with reference to the following drawings;

FIG. 2 illustrates a physical set-up of a syndrome measurement.

FIG. 3 illustrates a method 300 for processing encoded quantum information in a quantum computer.

FIG. 4 illustrates a quantum computer.

FIG. 5 illustrates a distance d=3 surface code using N=(2d−1)²⁼²⁵ physical qubits.

FIG. 6a illustrates a circuit to measure each Kₚ operator. FIG. 6b illustrates a circuit to measure each Kᵥ operator.

FIG. 7a illustrates a logical Z operator for a N=25 qubit planar code. FIG. 7b illustrates a logical X operator for a N=25 qubit planar code.

FIG. 8 illustrates an algorithm for calculating a resultant logical state.

FIG. 9 illustrates quantum circuits that consume a logical non-Clifford state as an input to realise a non-Clifford gate on quantum information.

### DESCRIPTION OF EMBODIMENTS

### Error Correction

Error correction is an important aspect of many physical information systems, such as communication networks. For example, a single bit having a value of ‘0’ can be flipped by an error to a value of ‘1’. This can be corrected by a repetition error correction code, where each logical bit is represented by three physical bits, so that logical bit values ‘0’ is represented by a physical bit value of ‘000’ of three physical bits. If one bit changes due to an error, this may result in ‘001’. A majority vote can then determine that the bit value needs to be corrected to ‘0’.

It may be tempting to apply the same principle to qubits in a quantum environment but the problem with quantum states is that they get destroyed by measuring them. In particular, superposition states that are a superposition of |0> and |1> states collapse into one of those states by measuring them. This means a direct application of repetition error codes is not possible.

However, it is possible to measure some information about errors in the quantum system without measuring the actual value of the qubits themselves. In a classical analogy, there may be a repetition code of eight physical bits for one logical bit. As a result, a logical ‘0’ is encoded as a physical ‘00000000’ and a logical ‘1’ is encoded as a physical ‘11111111’. Now the error correction code could check for a pairwise difference in bit value instead of absolute bit value. So for the logical ‘0’ value this could be written as ‘0=0=0=0=0=0=0=0’. Each pairwise parity check is valid. The same applies to the physical state ‘11111111’. However, if one bit flips, there are two pairs where the parity is not equal, such as ‘0=0=0< >1< >0=0=0=0’, where the fourth physical bit has flipped from ‘0‘ to’1’. As a result, the equality ‘=’ has changed to an inequality ‘< >’. If there is an inequality, it can be deduced that an error has occurred.

### Quantum Error Correction

This concept can be applied to qubits such that the value of the qubits is not measured but the relative values are measured. These measurements are referred to “syndromes” and are typically performed by ancilla qubits. FIG. 2 illustrates a physical set-up of a syndrome measurement, where the black circles 201-204 represent data qubits and the white circle 205 represents an ancilla qubit. The ancilla qubit is used to provide the syndrome measurement while the black qubits hold the data. For example, the black qubits could all be set to the ground state to encode a logical |0> state by a physical |0000> state. The ancilla qubit is initialised to |0> and the syndrome measurement comprises four CNOT gates on the ancilla qubit that are controlled by the data qubits, respectively. If all data qubits are |0000>, the syndrome measurement would be |0> because none of the CNOT gates would flip the ancilla state. Conversely, if the data qubits are |1111>, then there would be four flip operations, which again results in a |0> ancilla state. However, if there is an odd number of bi flip errors in the data qubits, there will be an odd number of flips of the ancilla qubit, which means the syndrome measurement will be |1>. This means a syndrome measurement of |0> would indicate no error while a syndrome measurement of |1> would indicate an error.

The above example is a simplified version of the surface code noting that actual implementations typically have a more complicated encoding, not just all |0> or all |1> but different encodings with potential superposition of states across the number of physical qubits. Further, syndrome measurements do not only include measurements for a square as shown in FIG. 2 (referred to as “plaquette”) but also to crosses (referred to as “vertex”) to detect X as well as Z type errors.

It is also noted that the physical qubits, that is four qubits in FIG. 2, represent a single logical qubit. So, for example, the physical state of |0000> represents a logical state of |0>. In other examples, a superposition state encodes a |0> state. It is then possible to apply operations on the logical state, such as flipping the logical state to realise an X gate. Such a gate, and many other gates, can be implemented, by applying corresponding operations to the multiple physical qubits. For example, in some configurations of the error code, a flip of qubits in one row of the lattice constitutes the application of an X gate, while a flip of qubits in one column of the lattice constitutes the application of a Z gate. Most gates (Clifford gates) on the logical qubits can be implemented relatively easily. Non-Clifford gates can also be implemented theoretically but the practical problem is that current physical quantum computers do not have a sufficient number of qubits to accommodate the overhead from implementing non-Clifford gates with techniques such as state distillation.

Applying multiple of these gates overtime and correcting detected errors at each step, enables the implementation of complex quantum algorithms, such as Shor or Grover algorithms. Since errors are corrected at each step, the overall execution is error resistant.

### Logical Qubits

In summary, there are physical data qubits that encode the quantum information that is to be processed in the quantum computer. More specifically, a number of physical data qubits together encode a single logical qubit state. Further, there are physical ancilla qubits. Often, these ancilla qubits are initialised with a |0> state. Operations on the physical ancilla qubits result in the syndrome measurements that give clues about the errors that occurred in the data qubits but without revealing any information about the actual value of the data qubits, which would otherwise destroy the state of the data qubits.

This disclosure further uses the notion of a “logical ancilla state”. This does not refer to the state of a physical ancilla qubit, but to a logical state, that is encoded on a number of physical data qubits. So similar to the above description, where a logical state is encoded in the data qubits 201-204, this encoded state can be used as a logical ancilla state by operations on logic qubit states. That is, the logical ancilla state can be an input of a logical quantum operation. This is also referred to as the logical quantum operation consumes the logical ancilla state. For example, the logical ancilla state may be initialised to a pre-determined value, and then CNOT gates can be applied to that ancilla state where the CNOT gates are controlled by respective logical states of the data qubits. In that sense, the ancilla state is different from the data state because it is set to a predetermined value and used to implement a non-Clifford gate. In the physical sense, however, the ancilla state is similar to the logical data state because it is also implemented by a number of physical data qubits, stabilised by physical ancilla qubits as described above.

### Method

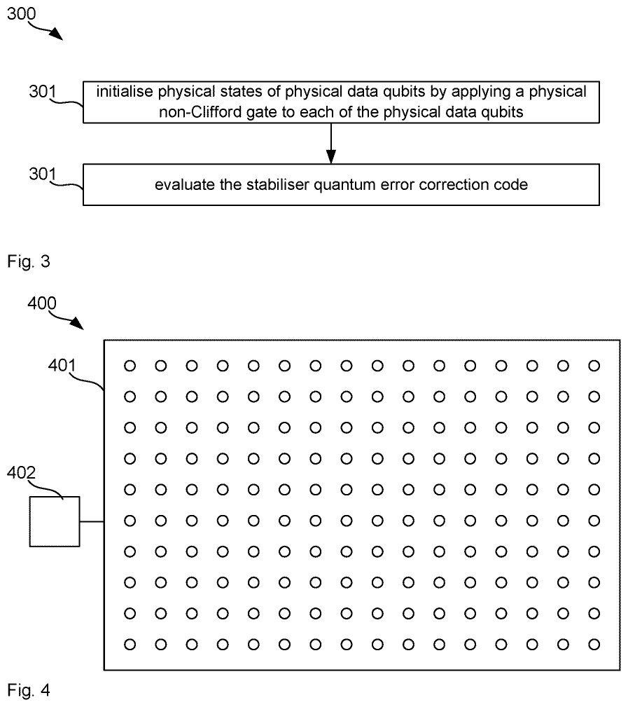

FIG. 3 illustrates a method 300 for processing encoded quantum information in a quantum computer. FIG. 4 illustrates a quantum computer 400 comprising multiple physical qubits (circles) 401 and a control system 402. FIG. 4 is a simplified schematic view, noting that further physical systems are typically involved, such as cooling and electrical/optical connectivity. The qubits may be implemented in a range of technologies, such as Phosphorus qubits is silicon, Nitrogen vacancies in diamond, trapped ions, photons and even superconducting qubits. Qubits 401 comprise physical data qubits and physical ancilla qubits as described herein. Further, qubits 401 together may constitute a single logical qubit and a quantum algorithm is performed on the single logical qubit. In other example, qubits 401 are separated into multiple blocks, while each block constitutes a logical qubit and the quantum algorithm operates on the multiple logical qubits. Qubits 401 may be arranged in an array that may be rectangular, square or have a different shape.

Control system 402 comprises a control signal generator, which may be a laser, radio frequency source or controllable magnet. The control signal initialises and controls the physical qubits as described herein. Control system 402 may also comprise a classical processor that, by executing program code installed thereon, performs classical computations to facilitate the methods disclosed herein. In particular, the classical computer performs the steps of encoding and decoding quantum states as well as processing syndrome measurements to then control the signal generator to correct detected errors. Control system 402 further orchestrates the running of the quantum algorithm, such as by providing input data and collecting output data of the algorithm. Control system 402 may also provide a user interface, such as on a computer screen or as a website over the internet to enable configuration and operation by a user. Control system 402 may also expose an application programming interface to enable execution of quantum algorithms by other software systems. Further, quantum computer 400 may be implemented within a classical computer system as a quantum co-processor or as an addition to an existing supercomputer server architecture. Further, different applications and implementations are equally possible.

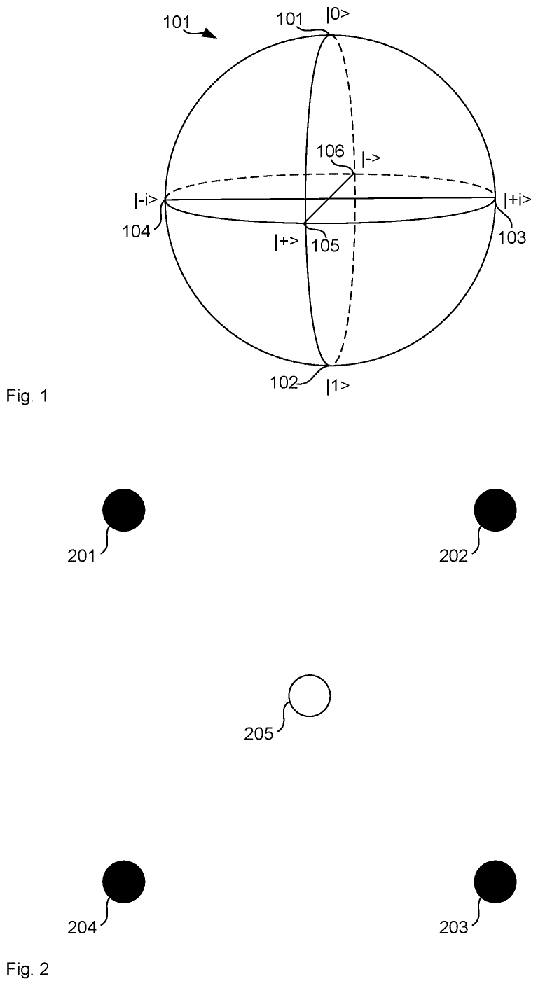

The control system 402 of quantum computer 400 uses a stabilizer quantum error correction code, such as a surface code, for example. Returning to FIG. 3, method 300 commences by initialising 301 physical states of physical data qubits in a logical block of the stabilizer quantum error correction code by applying a physical non-Clifford gate to each of the physical data qubits, to define an encoded quantum state encoded by the physical data qubits in the logical block. As explained with reference to FIG. 1, the application of a physical non-Clifford gate results in a physical quantum state that is not reachable by any Clifford gate. That quantum state is referred to as a non-Clifford state and may also be referred to as a non-stabilised quantum state. In particular, the non-Clifford state is not one of the states of |0>, |1>, |+>, |−>, |+i>, |−i>. In one example, the physical data qubits are initialised to the same non-Clifford state.

The exact non-Clifford gate can be calculated as described below. More particularly, the non-Clifford that that is applied to the physical qubits can be calculated based on the distance of the error correction code and based on the desired quantum gate at the logical level, such as a logical T gate. Again, as described above, Clifford gates on the logical qubit can be realised relatively easily by flipping qubits along a vertical or horizontal line on the lattice, for example. Now, by initialising the physical qubits with a non-Clifford gate, a non-Clifford logical state is available. This non Clifford logical state can be used to realise a non-Clifford logical gate on the quantum information relatively easily as well, thus reducing the number of required qubits significantly.

The next step of method 300 as evaluating 301 the stabilizer quantum error correction code to realise a desired quantum logic function and suppress quantum errors. That is, the error correction code provide syndrome measurements that are indicative of an error occurred on the data qubits. From these measurements, control system 402 can determine which qubits to adjust in order to correct the error.

Further, the desired quantum logic function is realised by a quantum gate that consumes the encoded quantum state as an input. The encoded quantum state is the result of applying the physical non-Clifford gate to each of the physical data qubits. This realizes a logical non-Clifford gate on the encoded quantum information.

### Surface Code Example

The methods disclosed herein are applicable to all stabilizer quantum error correction codes. One example is the planar surface code, which is a quantum error correcting code that is defined over a two dimensional square lattice of quantum bits (qubits). The code is parameterised by the code distance, d, that specifies the minimum number of physical errors required to create a logical error-a logical error is when the encoded information is fully corrupted. A planar surface code of distance d is guaranteed—when decoded correctly—to correct at least t=└(d−1)/2┘physical errors on any of the physical qubits in the logical block.

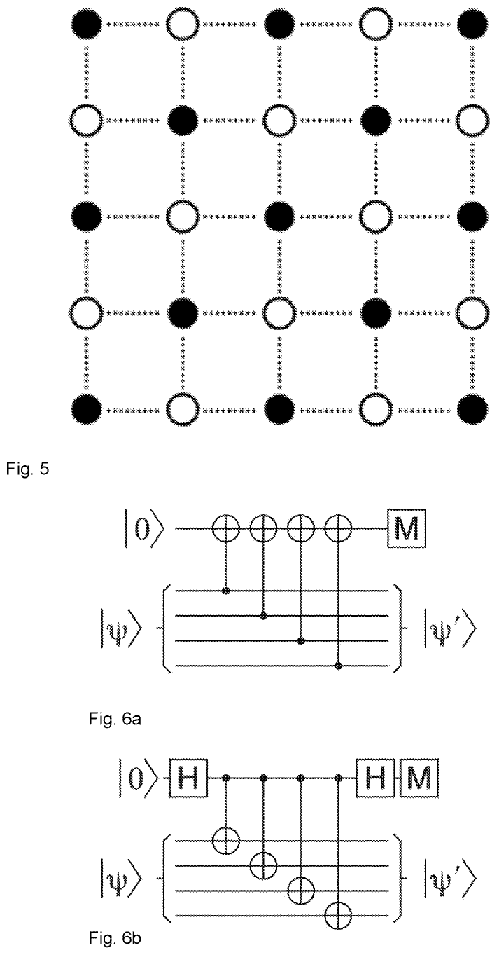

A distance d planar surface code is a 2D lattice of N=(2d−1)² physical qubits arranged in a square grid of edge length 2d−1. There are variants of this code such as the rotated surface code—which is defined over a N=2d² lattice—and the toric code-defined over a 2D lattice with periodic boundary conditions—for which transversal injection will also work, we will restrict our discussion to the planar code without loss of generality. A distance d=3 planar surface code is illustrated in FIG. 5. The distance d is a design parameter that can be chosen based on the circumstances. For example, a lower error rate in each physical qubit would lead to a smaller distance to achieve a sufficiently low error rate of the surface code. Vice versa, if the physical qubits are relatively unstable, a larger distance would be used. Example distances are 3 or 5 all the way up to 50. Again, the advantage of the methods disclose herein is that a relatively large distance can be realised in existing or near-future quantum technologies because the overall number of qubits is significantly reduced. This is compared to other methods that rely on state-distillation, for example, which require so many qubits that they cannot be manufactured currently because current technologies are limited by the number of qubits they can implement.

As explained above with reference to FIG. 2, the physical qubits—circles—in FIG. 5 are divided into two sets. The first set are coloured black and are the data qubits of the code, these are the physical qubits that comprise the encoded block of information. The second set, illustrated in white, are known as syndrome qubits (or physical ancilla qubits) and are used to extract information regarding quantum errors by performing parity check circuits on their four immediate data qubit neighbours—the four (three if located on a boundary) black qubits to the north, south, east and west of each white qubit. The dotted lines in FIG. 5 represents the interactions in the 2D lattice. Each physical qubit (data and ancilla) is able to perform a switchable quantum gate to each of the four nearest neighbours on the two dimensional grid. The physical architecture is consequently referred to as a two dimensional nearest neighbour array (2DNN).

For a N=(2d−1)×(2d−1) array, the number of data (black qubits) is B=d²+(d−1)² and the number of syndrome qubits (white) is W=2d(d−1). Note that the 2D array does not need to be square. A rectangular array can be used when physical quantum errors are biased—i.e. one type of quantum error is more likely than another. Without loss of generality, we will only describe square lattices.

Quantum error correction occurs by continuously operating the circuits show in FIGS. 6a and 6b over groups of four (if on a boundary) or five qubits. Each circuit involves one syndrome qubit at the top of FIGS. 6a and 6b and four data qubits and are known as parity check circuits for code stabilizers of the planar surface code. The syndrome qubit in FIGS. 6a and 6b corresponds to a white circle in FIG. 5 at the centre of four/three black circles (data qubits). These circuits project groups of four qubits into +1 or −1 eigenstates of the code stabilizers (i.e. ancilla qubits), with the measurement in each circuit providing a single bit of syndrome information and determining if the projected eigenstate is +1 or −1.

The stabilizer set consists of two types of operators. The first is the set of Z° 4 operators which circle every lattice face (or plaquette), or square as in FIG. 2. The second is the set of X©⁴ operators which encircle every vertex of the lattice, or cross (not shown in FIG. 2). The stabilizer set is consequently generated by the operators,

$${K}_{p} = {⊗}_{j ϵ b ( p )} {Z}_{j} , {K}_{v} = {⊗}_{j ϵ s ( v )} {X}_{j} \qquad ( 1 )$$

where b(p) is the four qubits surrounding a plaquette and s(v) is the four qubits surrounding each vertex in the lattice and identity operators on the other qubits are implied.

If the B=d²+(d−1)² physical data qubits are in +1 eigenstates of all of the stabilizer operators (Kₚ, Kᵥ) we refer to the group of B physical data qubits as being in an encoded logical—or codeword—state. The goal of error correction is to repeatedly measure each of these operators and ensure, through classical decoding of the W qubit measurements that the encoded state remains in a +1 eigenstate of each operator during the operational time of the encoded quantum computer.

The encoded block formed from the B data qubits also defines an encoded quantum state, |ϕ [symbol] _{L}. All valid logical states must be eigenvalues of every stabilizer operator, i.e. Kₚ|ϕ [symbol] _{L}=±|ϕ [symbol] _{L} and Kᵥ|ϕ [symbol] _{L}=±|ϕ [symbol] _{L} for all p and v. It is noted that the eigenstates may be states where some physical qubits are in the |0> state while others are in the |1> state. As a result, these eigenstates include superposition states of the physical qubits in the form of: a |000000000>+b|000000000001>+c |000000000010>+ . . . .

As there are a total of B data qubits in an encoded block and there are a total of B−1 stabilizer operators, ΣKₚ+ΣKᵥ=B−1, the dimensionality of the subspace that satisfies the eigen-condition of the stabilizers is two, i.e. the planar surface code only allows for two distinct states to be encoded, i.e. a single logical qubit.

These two encoded states are denoted as |0 [symbol] _{L} and |1 [symbol] _{L}, where the index L indicates that this as a logical state of a block of multiple data qubits as opposed to a physical state, e.g., |0>, of a single physical qubit. These two logical basis states are +1 and −1 eigenstates of a logical Z-operator. This Z operator commutes with all stabilizer operators Kₚ and Kᵥ, but is not a member of the group generated by Kₚ and Kᵥ. This operator corresponds to a chain of physical Z-operators that span the lattice from the left to the right.

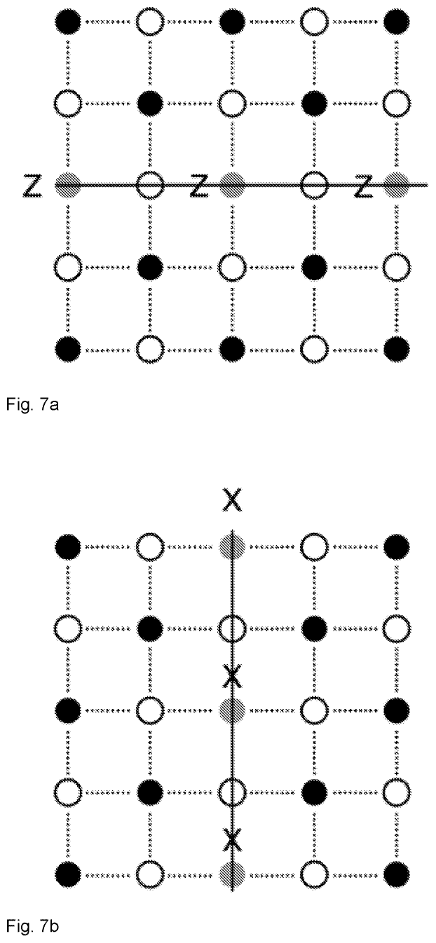

As the quantum computer encodes a qubit of information, there is a conjugate X-type logical operator that anti-commutes withe the Z-type logical operator—i.e. X_{L}·Z_{L}+Z_{L}·X_{L}=0—that defines the |+ [symbol] _{L}=(|0 [symbol] _{L}+|1 [symbol] _{L})/\sqrt{2} and |− [symbol] _{L}+(|0 [symbol] _{L}−|1 [symbol] _{L})/\sqrt{2}, states. This is a chain of physical X-operations that span the lattice from top to bottom. FIG. 7a illustrates for the Z operator and FIG. 7b for the X operator. Again, these operators are Clifford gate operators that can be realised by these relatively uncomplicated operations on a row or column of qubits.

Besides these basic qubit operations, it is also possible to apply a quantum gate to the encoded logical state, where that quantum gate has a further input. Typically, that further input is a logical qubit with a state that is initialised to a pre-determined value. Such a further qubit that is used as an input to the quantum gate, which then acts on the encoded data, is referred to as a logical ancilla qubit, noting that the value of the logical ancilla qubit is also encoded in multiple physical data qubits and stabilised by physical ancilla qubits.

Initialisation of a logical ancilla qubit consists of the following steps:
1. Choose the basis for initialisation, either X-basis (|+ [symbol] _{L}, |− [symbol] _{L}) or Z-basis (|0 [symbol] _{L}, |1 [symbol] _{L}).
2. If Z-basis is chosen, physically initialise every data qubit, B, into the physical 0 [symbol] state.
3. If X-basis is chosen, physically initialise every data qubit, B, into the physical |+ [symbol] state.
4. Run the circuits in FIGS. 6a and 6b to measure and project the data block into the logical state.
5. Run the circuits in FIGS. 6a and 6b a further d−1 times to gather sufficient syndrome information.
6. Decode the syndrome information and apply suitable corrections to ensure the encoded block is in +1 eigenstates of all Kₚ and Kᵥ.

This will initialise the encoded block into either the |0 [symbol] _{L} if Z-basis is chosen or |+ [symbol] _{L}if X-basis is chosen.

The reason this performs initialisation into the appropriate state is because when Z-basis (X) is chosen and each physical qubit is initialised in the |0 [symbol] (|+ [symbol] ) state, the eigen-condition of the Z-logical (X-logical) operator is already satisfied before any encoding is performed. Since each stabilizer of the planar surface code, by definition, commutes with the logical operator, measuring the code stabilizers to initialise the encoded block does not change the eigen-condition for the logical operator. Consequently, at the end of the code initialisation procedure, the encoded state of the logical qubit is ‘left-over’ as a remnant of the initial choice for each of the data qubits in the block. i.e. if physical |0 [symbol] states are chosen, we are left with a |0 [symbol] _{L} state, if physical |+ [symbol] states are chosen, we are left with a |+ [symbol] _{L} state.

This is the fault-tolerant initialisation procedure for the planar surface code for two Clifford states, |0 [symbol] _{L} and + [symbol] _{L}.

### Transversal Injection

Transversal injection is the realisation that the above procedure is only a small subset of what is actually possible in the planar surface code. It was assumed that |0 [symbol] _{L} and |+ [symbol] _{L} states were the only two states that could be fault-tolerantly initialised in this manner. This disclosure shows that this is not true and a much broader class of states can be initialised fault-tolerantly on the planar surface code.

In this disclosure, quantum computer 400 places all the data qubits initially into the states

$${\vert χ 〉}_{i} = α \vert 0 〉 + β \vert 1 〉 , ∀ i ϵ \{ B \} \qquad ( 2 )$$

i.e. quantum computer 400 first performs a transversal rotation on all data qubits to the state |χ [symbol] before it follows steps 3-5 above. The Clifford states |0 [symbol] _{L} and |+ [symbol] _{L} initializations become special cases when |χ [symbol] =|0 [symbol] or |χ [symbol] =|+ [symbol] .

As the qubits are no longer in eigenstates of the logical Z—or X operator of the surface code, after measurement of the stabilizers quantum computer 400 will be left with an encoded state that is in some superposition of these operators and hence some non-trivial logically encoded state. This state can be calculated prior to encoding.

### Calculation of the Resultant Logically Initialised

First we examine how an array of physical qubits, initialised in the |0 [symbol] state give rise to a logically encoded |0 [symbol] _{L} state after steps 3-5 above. This can be done by examining how the stabilizer set evolves during the initialisation procedure.

For an array of B qubits, the stabilizer set consists of the B operators,

$$( \begin{matrix}{z}_{1} \\ {z}_{2} \\ … \\ … \\ {z}_{B}\end{matrix} ) ( \begin{matrix}{Z}_{1} & I & I & … & I \\ I & {Z}_{2} & I & … & I \\ I & I & {Z}_{3} & … & I \\ … & … & … & … & … \\ … & … & … & … & … \\ I & I & I & … & {Z}_{B}\end{matrix} ) \qquad ( 3 )$$

In this notation, the first column vector represents the eigenvalues, ±1, for each of the B stabilizer operators that define the initial state. If a physical data qubit, j, is initialised in the |0 [symbol] ⱼ state, zⱼ=+1 and if it is initialised in the |1 [symbol] ⱼ state, zⱼ=−1.

Quantum computer 400 now measures all of the code stabilizers by running the quantum circuits shown in FIGS. 6a and 6b. The circuits for the vertex stabilizers, Kᵥ are run first (FIG. 6b) as they measure operators that do not commute with the initial array.

The first step is that the resultant state is projected into eigenstates of the X-stabilizers, Kᵥ, with the eigenvalue for each operator determined by the qubit measurements of each stabilizer circuit in FIG. 6b. These projections are random.

The set of measurements for each stabilizer, Kᵥ defines a stabilizer trajectory for initialisation in the X-sector, denoted by the B/2 string {x₀, x₁, . . . , x_{B/2-1}} of eigenvalues (xⱼ∈ {+1, −1}) that are measured for the B/2, X-type stabilizers, Kᵥ.

To calculate the resultant set of stabilizers for the encoded state, quantum computer 400 multiplies rows of Eq. 3 so that they commute with each of the X-type stabilizers that form the operators we measure in step 4 above, Kᵥ.

By definition for the planar stabilizer code, the only combination of Z-stabilizers that commute with all Kᵥ are the Z-type stabilizers of the code, Kₚ and a chain operator, spanning the lattice from left to right, that denotes the logical Z-operator. Hence quantum computer 400 uses each row of operators in Eq. 3 and forms the Kₚ stabilizers of the planar code and a single left/right chain operator to add to the new stabilizer set that consists of the X-operators that are already measured.

$$( \begin{matrix}{x}_{1} \\ {x}_{2} \\ … \\ … \\ {x}_{B / 2} \\ {z}_{{K}_{p 1}} \\ {z}_{{K}_{p 2}} \\ … \\ {z}_{{K}_{p ( B / 2 )}} \\ {z}_{chain}\end{matrix} ) ( \begin{matrix}{K}_{v 1} \\ {K}_{v 2} \\ … \\ … \\ {K}_{v ( B / 2 )} \\ {K}_{p 1} \\ {K}_{p 2} \\ … \\ … \\ … \\ {K}_{p ( B / 2 )} \\ {Z}_{L}\end{matrix} ) . \qquad ( 4 )$$

While the string {x₀, x₁, . . . , X_{B/2-1}} is determined from the measured eigenvalues of the X-type stabilizers, Kᵥ, the eigenvalues of the Z-type stabilizers and the chain operator defining the logical state of the encoded block is a modulo two sum of the original eigenvalues of Eq. 3, that occurs when quantum computer 400 multiplies the original stabilizers generators in Eq. 3 together to form each of the operators, Kₚ and Z_{L}. For example, if Kₚ₁=Z₁Z₂Z₃, i.e. qubits labelled one, two and three in the lattice form the first Z-type stabilizer, then z_{K}_{ₚ₁}=(z₁+z₂+z₃)mod 2.

When quantum computer 4000 initialises into the |0 [symbol] _{L} state, there would now already be a logically encoded state (as all the Z-type stabilizers should automatically be satisfied), however these stabilizers are still measured anyway for a fault-tolerant initialisation. In this case, the measurements of each of the Kₚ stabilizers should simply result in the eigenvalue string given by {Z_{K}_{ₚ₁}, Z_{K}_{ₚ₂}, . . . , Z_{K}_{_{p(B/2)}}}, which are formed through modulo two sums of the original eigenvalues.

The logical state that the block is initialised into is also determined via z_{chain}=Σ_{i∈left/right}zᵢ mod 2 of a chosen chain that runs from the left boundary to the lattice. if z_{chain}=0 we have initialised the logical qubit into the |0 [symbol] _{L} state and if z_{chain}=1, the |1 [symbol] _{L} state.

When all qubits are initialised into a transversally rotated state, |X=α|0 [symbol] +β|1 [symbol] before encoding, the qubits are now not simply in ±1 eigenstates of Z in Eq. 3. Instead, the qubits are in superpositions of the +1 and −1 eigenstates, i.e.

$${\vert χ 〉}_{i} = α ( + {Z}_{i} ) + β ( - {Z}_{i} ) \qquad ( 5 )$$

Consequently, the B data qubits in the planar code will initially be in the state

$${\vert χ 〉}^{{⊗}_{B}} = {α}^{B} ( \begin{matrix}{Z}_{1} & I & I … & I \\ I & {Z}_{2} & I … & I \\ … & … & … & … \\ I & I & I … & {Z}_{B}\end{matrix} ) + {α}^{B - 1} β [ ( \begin{matrix}- {Z}_{1} & I & I … & I \\ I & {Z}_{2} & I … & I \\ … & … & … & … \\ I & I & I … & {Z}_{B}\end{matrix} ) + ( \begin{matrix}{Z}_{1} & I & I … & I \\ I & - {Z}_{2} & I … & I \\ … & … & … & … \\ I & I & I … & {Z}_{B}\end{matrix} ) + … + ( \begin{matrix}{Z}_{1} & I & I … & I \\ I & {Z}_{2} & I … & I \\ … & … & … & … \\ I & I & I … & - {Z}_{B}\end{matrix} ) + {αβ}^{B - 1} [ ( \begin{matrix}{Z}_{1} & I & I … & I \\ I & - {Z}_{2} & I … & I \\ … & … & … & … \\ I & I & I … & - {Z}_{B}\end{matrix} ) + ( \begin{matrix}- {Z}_{1} & I & I … & I \\ I & {Z}_{2} & I … & I \\ … & … & … & … \\ I & I & I … & - {Z}_{B}\end{matrix} ) + … + ( \begin{matrix}- {Z}_{1} & I & I … & I \\ I & - {Z}_{2} & I … & I \\ … & … & … & … \\ I & I & I … & {Z}_{B}\end{matrix} ) ] + {β}^{B} ( \begin{matrix}- {Z}_{1} & I & I … & I \\ I & - {Z}_{2} & I … & I \\ … & … & … & … \\ I & I & I … & - {Z}_{B}\end{matrix} ) \qquad ( 6 )$$

Eq. 6 is effectively a binomial expansion in α and β where the initial Z-type stabilizers of Eq. 3 are a superposition of all of the 2^{B} combinations of the initial |0 [symbol] and |1 [symbol] states that are possible when B qubits are transversally rotated into the state |X

[symbol]

Since the stabilizer sets transform from the original diagonal form of Z to the stabilizers and logical operators for the encoded planar code, quantum computer 400 can treat each term individually and follow them through the encoding procedure.

The first step in encoding is to measure all the X-type stabilizers, Kᵥ. As noted before, the measurement of these stabilizers will result in a random eigenvalue sequence for the X-type stabilizers and project a stabilizer set that is diagonal in Z, straight into an encoded state with Z-stabilizer eigenvalues and the eigenvalue of the logic operator given by modulo two sums of their original eigenvalues. Quantum computer 400 retains the superposition of the Z-type stabilizers at this point as it has not yet actively measured their eigenvalues.

After the X-type stabilizers are measured, the resultant B qubit state is given by,

$${α}^{B} ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) + {α}^{B - 1} β [ ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{(} {\sum {z}_{i}}_{i ϵ {Z}_{L}} ) {Z}_{L}\end{matrix} ) + ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) + … + ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) + {αβ}^{B - 1} [ ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) + ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) + … + ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) ] + {β}^{B} ( \begin{matrix}{( - 1 )}^{{M}_{{x}_{1}}} {X}_{1} \\ {( - 1 )}^{{M}_{{x}_{2}}} {X}_{2} \\ … \\ {( - 1 )}^{( {\sum {z}_{i}}_{i ϵ {Z}_{1}} )} {Z}_{1} \\ {( - 1 )}^{( {\sum {z}_{i}}_{i ϵ {Z}_{2}} )} {Z}_{2} \\ … \\ {( - 1 )}^{( {\sum {z}_{i}}_{i ϵ {Z}_{L}} )} {Z}_{L}\end{matrix} ) \qquad ( 7 )$$

Where, Mₓ_{₁} and Mₓ_{₂} are the parity measurements of the X-stabilizers (which are random). The sums, Σ_{i∈Z1} Zᵢ are the ±1 eigenvalues of the original one-dimensional Z-stabilizers, calculated as a sum over the Z-stabilizers of the code (similarly for the logical operator, Z_{L}). Quantum computer 400 now measures the Z-type stabilizers.

Unlike when initialising into the |0 [symbol] _{L} or |1 [symbol] _{L} state, the qubits are not already in eigenstates of the Z-type stabilizers, hence the outcome of these measurements will be random and will in effect, select out only certain terms in Eq. 7 that are consistent with the measurements observed. Like with the X-type stabilizers, we now denote the string {z₁, z₂, . . . , Z_{B/2}} as the measured eigenvalues of the Z-type stabilizers. This defines another stabilizer trajectory that can consist of 2^{B/2} possible paths, in a similar manner to the X-type stabilizer trajectory.

Since quantum computer 400 follows only one of the 2^{B/2} possible stabilizer trajectories when it initialises the code, it selects out only the terms in Eq. 7 that are consistent with the eigenvalues we measure. For example, if z₁=+1, for stabilizer Kₚ₁=Z₁Z₂Z₃, then quantum computer 400 can only keep the terms in Eq. 7 where z_{K}_{ₚ₁}=(z₁+Z₂+z₃)mod 2=0. Any term where Z_{K}_{ₚ₁}=1 will be inconsistent with the measurement projection that actually occurred and will be simply projected out of the resultant state.

This results in a superposition of only the terms from Eq. 6 that are consistent with the X- and Z-stabilizer trajectories that are observed when initialising the state. By definition—as quantum computer 400 has now stabilized its data qubits with respect to all stabilizers of the planar code—the result is some superposition of the logic operator, Z_{L}, i.e. some new encoded state, α_{L}|0 [symbol] _{L}+β_{L}|1 [symbol] _{L}. Note that the resultant logical state does not, in general, match the transversal state, |χ [symbol] that was used to initialise each of the physical qubits in the encoded block. In other words, the physical qubits are initialised by a non-Clifford quantum gate which has the effect of a different logical non-Clifford quantum gate being applied to initialise the logical ancilla state.

The superposition of the logical basis states, |0 [symbol] _{L} and |1 [symbol] _{L} can be calculated by either selecting out the coefficients from Eq. 7, after the Z-stabilizer measurements have selected out a subset of terms, where z_{chain}=+1 and z_{chain}=−1.

After renormalising the wave function, there is an analytical form of the resultant encoded state as a function of α,β and B. Note that the logical state that is initialised is a function of several variables.
1. The logical state depends on α and β, chosen as the initial transversal rotation of all the data qubits.
2. The logical state depends on the total number of data qubits and hence code distance, B=d²+(d−1)².
3. The logical state depends on the X-type stabilizer trajectory and the string, {x₁, x₂, . . . , x_{B/2}}, of measured eigenvalues when the planar code is initially stabilized.
4. The logical state depends on the Z-type stabilizer trajectory and the string, {z₁, z₂, . . . , z_{B/2}}, of measured eigenvalues when the planar code is initially stabilized.

As each of these are known once a planar code qubit is initialised, the resultant logical state can be used within a quantum algorithm. The probabilistic nature of the X and Z-type stabilizer measurements means that the resultant encoded state realised in a transversal injection is probabilistic, but heralded. Design tools for quantum algorithms can compensate for this probabilistic creation of encoded states when compiling quantum circuits and preparing non-Clifford encoded states to perform non-Clifford operations on encoded data.

It can be seen from the functional forms for d=2 that a variety of states are possible to encode, not just Clifford states. While the mapping between (α,β) and (α_{L}, β_{L}) is non-trivial, it is calculable and covers a trajectory over the logical Bloch sphere that encompasses a continuum of non-Clifford states.

### Algorithm for Calculating the Functional Form of Injected States

The above sections explain how analytical forms for the resultant logical state are calculated. The following disclosure presents an explicit algorithmic construction that can be used to derive the logical state for an arbitrary distance, d, surface code. This general formalism applies for all stabilizer quantum codes and without loss of generality we explicitly detail it for the surface code of a fixed code distance.

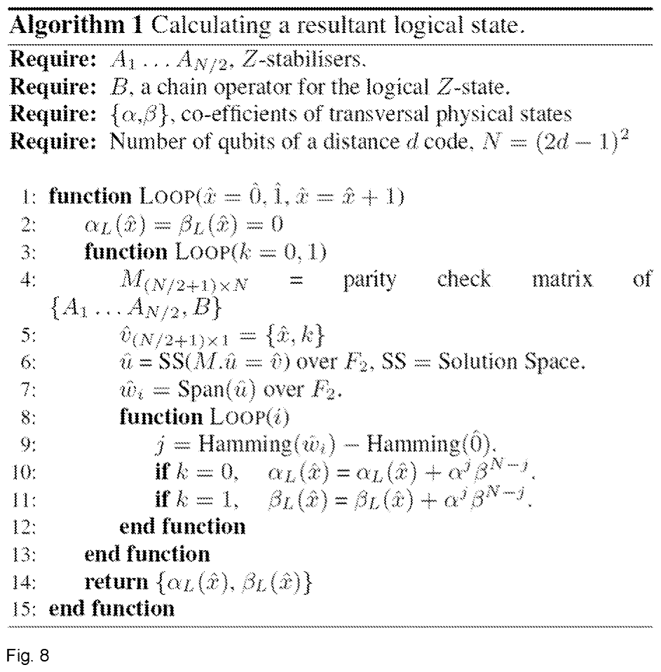

FIG. 8 illustrates an algorithm for calculating a resultant logical state. For example, for a distance d=2 code, there is a total of N=5 physical qubits, each of the matrices, M are 3×5 matrices formed from the two Z-stabilizers and one logical operator of the distance two surface code,

$$M = ( \begin{matrix}1 & 0 & 1 & 1 & 0 \\ 0 & 1 & 1 & 0 & 1 \\ 1 & 1 & 0 & 0 & 0\end{matrix} ) \qquad ( 8 )$$

Consequently, there are the four set of analytical equations (up to renormalisation) corresponding to the four sets of stabilizer trajectories, \hat{x}={00, 01, 10, 11}.

$$\begin{matrix}\hat{x} = , & ( \begin{matrix}{α}_{L} \\ {β}_{L}\end{matrix} ) = ( \begin{matrix}{α}^{5} + 2 {α}^{2} {β}^{3} + {αβ}^{4} \\ 2 {α}^{3} {β}^{2} + 2 {α}^{2} {β}^{3}\end{matrix} ) \\ \hat{x} = , & ( \begin{matrix}{α}_{L} \\ {β}_{L}\end{matrix} ) = ( \begin{matrix}{β}^{5} + 2 {β}^{2} {α}^{3} + {βα}^{4} \\ 2 {β}^{3} {α}^{2} + 2 {β}^{2} {α}^{3}\end{matrix} ) \\ \hat{x} = = , & ( \begin{matrix}{α}_{L} \\ {β}_{L}\end{matrix} ) = ( {α}^{4} β + {α}^{3} {β}^{2} + {α}^{2} {β}^{3} + {αβ}^{4} ) ( \begin{matrix}1 \\ 1\end{matrix} )\end{matrix} \qquad ( 9 )$$

Hence for only of two (out of four) measured stabilizer trajectories, there is a non-trivial set of logical states (\hat{x}={00, 11}) for the other two stabilizer trajectories (\hat{x}={01, 10}) quantum computer 400 simply initialise into the logical |+ [symbol] =(|0 [symbol] +|1 [symbol] )/\sqrt{2} state.

### Realising Non-Clifford Logic Operations Through Transversal Injection

The primary benefit of the above technique is that it eliminates the need for resource costly state distillation protocols to realise the encoding of high-fidelity non-Clifford states. Once this is achieved, quantum processor 400 can use gate teleportation protocols to realise non-Clifford gate, and complete a universal gate library for error-corrected quantum computation.

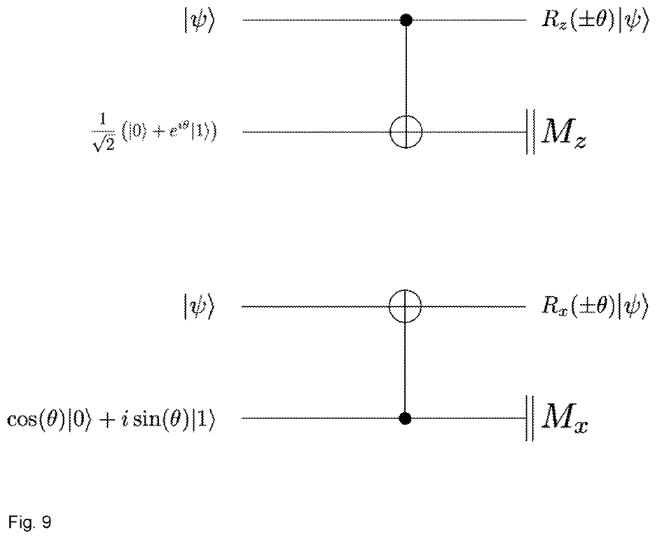

Consider the circuits shown in FIG. 9. In each of these circuits, there is the logical data qubit, |ψ [symbol] and an logical ancilla qubit that is prepared in the states, (|0 [symbol] +e^{iθ}|1 [symbol] )/\sqrt{2} or cos(θ)|0 [symbol] + i sin(θ)|1 [symbol] . The rest of the circuit consists of the Clifford gates, CNOT, and measurement in either the X- or the Z-basis. It can be easily verified that after the ancilla is measured, the resultant state is the rotated gate, R_{z}(±θ) or Rₓ(±θ) applied to the rate qubit, |ψ [symbol] , which is a non-Clifford gate. The angle, θ is determined by the exact for of the ancillary state and the ± is determined by the outcome of the measurement result on the ancilla.

Consequently, the ability to perform arbitrary single qubit rotations, becomes a problem of preparing appropriate logical ancillary states. If these states can be prepared in the encoded space, fault-tolerantly, then they can be consumed in the circuits of FIG. 9 to enact non-Clifford gates on encoded data. This transversal injection procedure prepares the encoded logical ancilla states and then uses standard gate teleportation circuits for the surface code to enact non-Clifford gates. This combined by the native Clifford gate that are allowed within the surface code, gives a universal set of quantum gate operations on the encoded data.

To match up the functional forms in Eq. 9 to the functional forms for the circuits in gate teleportation, quantum computer 400 solves

$$\begin{matrix}( \begin{matrix}1 \\ {e}^{i θ}\end{matrix} ) = & ( \begin{matrix}{α}^{5} + 2 {α}^{2} {β}^{3} + {αβ}^{4} \\ 2 {α}^{3} {β}^{2} + 2 {α}^{2} {β}^{3}\end{matrix} ) or ( \begin{matrix}{β}^{5} + 2 {β}^{2} {α}^{3} + {βα}^{4} \\ 2 {β}^{3} {α}^{2} + 2 {β}^{2} {α}^{3}\end{matrix} ) , \\ and ( \begin{matrix}cos ( θ ) \\ i sin ( θ )\end{matrix} ) = & ( \begin{matrix}{α}^{5} + 2 {α}^{2} {β}^{3} + {αβ}^{4} \\ 2 {α}^{3} {β}^{2} + 2 {α}^{2} {β}^{3}\end{matrix} ) or ( \begin{matrix}{β}^{5} + 2 {β}^{2} {α}^{3} + {βα}^{4} \\ 2 {β}^{3} {α}^{2} + 2 {β}^{2} {α}^{3}\end{matrix} )\end{matrix} , \qquad ( 10 )$$

for α,β and θ, in the case of the d=2 solution. Once we find specific forms of α and β that gives rise to these functional forms, we know what transversal injected states are needed on the physical qubits to generate the correct form of the encoded states to be used in the circuits in FIG. 9 to realise the R_{z}(θ) and Rₓ(θ) rotational gates.

Once quantum processor 400 has these arbitrary rotations around the X and Z-axis, it is able to use an Euler angle decomposition to achieve any arbitrary single qubit gate,

$$G = {R}_{z} ( α ) {R}_{x} ( β ) {R}_{z} ( γ ) , G ϵ SU ( 2 ) \qquad ( 11 )$$

Arbitrary single qubits gates, G, plus the ability to perform two-qubit CNOT gates and {|0 [symbol] , |1 [symbol] }qubit measurements is sufficient for universal quantum computation.

Consequently, transversal injection enables quantum computer 400 to realise the implementation of arbitrary single qubit gates in an encoded system. This combined with traditional error corrected operations in the surface code enables universal error-corrected computation without the need for state distillation protocols or other complex ancillary techniques.

### Broader Applicability

While this disclosure is focused specifically on the surface code, it does apply to a variety of different coding structures.

1. Transversal injection will apply to all stabilizer quantum error correction codes, and the algorithm can calculate resultant logical states given the stabilizer description of the code.

2. teleported quantum gates are applicable to all stabilizer codes that allow for a transversal CNOT operation.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

The invention claimed is:

1. A method for processing encoded quantum information in a quantum computer using a stabilizer quantum error correction code, the method comprising:
initialising physical states of physical data qubits in a logical block of the stabilizer quantum error correction code by applying a physical non-Clifford gate to each of the physical data qubits, to define an encoded quantum state encoded by the physical data qubits in the logical block; and
evaluating the stabilizer quantum error correction code to realise a desired quantum logic function and suppress quantum errors,
wherein evaluating the stabilizer quantum error correction code comprises consuming the encoded quantum state, resulted from applying the physical non-Clifford gate to each of the physical data qubits, to realise a logical non-Clifford gate on the encoded quantum information.

2. The method of claim 1, wherein the physical states for initialising the physical data qubits in the logical block are identical.

3. The method of claim 1, wherein the method further comprises determining the physical states based on a desired logical non-Clifford gate on the encoded quantum information.

4. The method of claim 3, wherein determining the physical states comprises solving one or more equations for two factors that define a superposition of two respective ground states of the physical data qubits.

5. The method of claim 4, wherein the one or more equations are based on a code distance of the stabilizer quantum error correction code.

6. The method of claim 1, wherein the method further comprises determining the encoded quantum state based on the physical non-Clifford gate applied to each of the physical data qubits.

7. The method of claim 6, wherein determining the encoded quantum state comprises analytically calculating the encoded quantum state as a function of the physical non-Clifford gate.

8. The method of claim 1, further comprising extracting syndrome information by measuring multiple physical ancilla qubits to suppress the quantum errors.

9. The method of claim 1, wherein the logical non-Clifford gate on the encoded quantum information is a T gate.

10. The method of claim 1, wherein the logical non-Clifford gate together with one or more logical Clifford gates, form a universal gate set for universal error-corrected computation.

11. The method of claim 1, wherein the number of data qubits is identical to the number of data qubits required to realise logical Clifford gates.

12. The method of claim 1, wherein the stabilizer quantum error correction code comprises a surface code.

13. The method of claim 1, wherein realising the logical non-Clifford gate comprises using the encoded quantum information and the encoded quantum state as respective inputs to a Clifford gate.

14. The method of claim 13, wherein the Clifford gate is a CNOT gate.

15. The method of claim 1, wherein one or both of the physical non-Clifford gate and the logical non-Clifford gate is a rotated gate.

16. A quantum processor comprising:
multiple physical data qubits operable in a stabilizer quantum error correction code; and
a control system configured to:
initialise physical states of the multiple physical data qubits in a logical block of the stabilizer quantum error correction code by applying a physical non-Clifford gate to each of the physical data qubits, to define an encoded quantum state encoded by the physical data qubits in the logical block; and
evaluate the stabilizer quantum error correction code to realise a desired quantum logic function and suppress quantum errors,
wherein evaluating the stabilizer quantum error correction code comprises consuming the encoded quantum state, resulted from applying the physical non-Clifford gate to each of the physical data qubits, to realise a logical non-Clifford gate on the encoded quantum information.

17. A quantum processor comprising:
multiple physical data qubits operable in a stabilizer quantum error correction code;
a first quantum circuit configured to operate on the multiple physical data qubits and comprising a physical non-Clifford gate to initialise physical states of the multiple physical data qubits in a logical block of the stabilizer quantum error correction code, to define an encoded quantum state encoded by the physical data qubits in the logical block; and
a second quantum circuit configured to operate on the encoded quantum state and on encoded quantum information and comprising only one or more logical Clifford gates to realise, by taking the encoded quantum state as an input, a logical non-Clifford gate on the encoded quantum information.
